(19) United States
(12) Patent Application Publication
(10) Pub. No.: US 2020/0258675 A1
(43) Pub. Date: Aug. 13, 2020

(54) HYBRID TRANSFORMER FOR DC/DC CONVERTER

(71) Applicant: Lear Corporation, Southfield, MI (US)

(72) Inventors: Rafael JIMENEZ PINO, Valls (ES); Oscar LUCIA GIL, Zaragoza (ES); Magi MARGALEF BOQUERA, Valls (ES); Hector SARNAGO ANDIA, Olvega (Soria) (ES); Antonio LEON MASICH, Valls (ES)

(21) Appl. No.: 16/783,744

(22) Filed: Feb. 6, 2020

Related U.S. Application Data
(60) Provisional application No. 62/802,780, filed on Feb. 8, 2019.

(51) Int. Cl. H01F 27/28; H01F 27/24; H05K 1/14; H01F 27/06; H05K 1/18; H02M 7/00

(52) U.S. Cl. CPC H01F 27/2876; H01F 27/24; H01F 27/2823; H05K 1/14; H05K 2201/1003; H05K 1/181; H02M 7/003; H05K 2201/042; H01F 2027/065; H01F 27/06

(57) ABSTRACT

In at least one embodiment, a transformer assembly is provided. The assembly includes a first printed circuit board (PCB), a magnetic core, a primary winding, and a secondary winding. The magnetic core is positioned about the first PCB. The primary winding is implemented as a wire assembly and is positioned on a first side of the PCB to interface with the magnetic core. The secondary winding is embedded within the first PCB to interface with the primary winding and the magnetic core to convert an input signal into a converted output signal.

### CROSS-REFERENCE TO RELATED APPLICATIONS

This application claims the benefit of U.S. provisional application Ser. No. 62/802,780, filed Feb. 8, 2019, the disclosure of which is hereby incorporated in its entirety by reference herein.

### TECHNICAL FIELD

Aspects disclosed herein may generally relate to a transformer including primary and secondary windings in which one of the windings is implemented as wiring and the other one of the windings is implemented as one or more metallic foils.

### BACKGROUND

U.S. Publication No. 2008/0297300 to Ackerman et al. provides primary and secondary windings that are subjected to a significant heat stress during operation of a high voltage transformer. Ackerman further discloses that a high voltage transformer is believed to have good temperature properties. This transformer may have a planar primary winding and a Litz secondary winding. The planar primary winding may abut against a planar face of the core thereby allowing for a good heat exchange between these two elements. The Litz secondary winding and the planar primary winding may be cooled by means of a cooling medium.

### SUMMARY

In at least one embodiment, a transformer assembly is provided. The assembly includes a first printed circuit board (PCB), a magnetic core, a primary winding, and a secondary winding. The magnetic core is positioned about the first PCB. The primary winding is implemented as a wire assembly and is positioned on a first side of the PCB to interface with the magnetic core. The secondary winding is embedded within the first PCB to interface with the primary winding and the magnetic core to convert an input signal into a converted output signal.

In at least another embodiment, a power conversion device including a transformer assembly is provided. The transformer assembly receives an input signal. The assembly includes a first printed circuit board (PCB), a magnetic core, a primary winding, and a secondary winding. The magnetic core is positioned about the first PCB. The primary winding is implemented as a wire assembly and being positioned on a first side of the PCB to interface with the magnetic core. The secondary winding is embedded within the first PCB to interface with the primary winding and the magnetic core to convert the input signal into a converted output signal.

In at least one embodiment, a transformer assembly is provided. The assembly includes a first printed circuit board (PCB), a magnetic core, a primary winding, and a secondary winding. The magnetic core is positioned about the first PCB. The primary winding is implemented as a Litz wire and is positioned on a first side of the PCB to interface with the magnetic core. The secondary winding is embedded within the first PCB to interface with the primary winding and the magnetic core to convert an input signal into a converted output signal.

### BRIEF DESCRIPTION OF THE DRAWINGS

The embodiments of the present disclosure are pointed out with particularity in the appended claims. However, other features of the various embodiments will become more apparent and will be best understood by referring to the following detailed description in conjunction with the accompany drawings in which:

FIG. 1 depicts an example of a perspective view for a transformer implementation (or transformer assembly) in accordance to one embodiment;

FIGS. 2A-2B generally depict one example of a printed circuit board (PCB) and at least a portion of a magnetic core that forms a portion of the transformer assembly of FIG. 1;

FIGS. 3A-3B generally depict one example of a primary winding that forms at least a portion of the transformer assembly of FIG. 1;

FIG. 4 generally depicts another example of transformer assembly including a plurality of transformers in accordance to one embodiment;

FIG. 5 generally depicts a top view of the PCB in accordance to one embodiment

FIG. 6 generally depicts an underside of the PCB that forms the transformer assembly in accordance to one embodiment'

FIG. 7 generally depicts a more detailed example of another transformer assembly in accordance to one embodiment;

FIG. 8 depicts a perspective view for another transformer assembly in accordance to one embodiment;

FIG. 9 depicts a perspective view of another transformer assembly in accordance to one embodiment;

FIG. 10 depicts a table of partitions of a secondary winding as embedded in various layers of the PCB in accordance to one embodiment; and

FIG. 11A-11D generally depict a top view for a corresponding a layer of the PCB with sectors and segments of the secondary winding.

### DETAILED DESCRIPTION

As required, detailed embodiments of the present invention are disclosed herein; however, it is to be understood that the disclosed embodiments are merely exemplary of the invention that may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present invention.

It is recognized that directional terms that may be noted herein (e.g., “upper”, “lower”, “inner”, “outer”, “top”, “bottom”, etc.) simply refer to the orientation of various components of a busbar assembly as illustrated in the accompanying figures. Such terms are provided for context and understanding of the embodiments disclosed herein.

A power conversion device such as, for example, a direct current (DC) to DC converter (hereafter “DC/DC converter) converts a DC input voltage from one value into a DC output voltage that differs from the DC input voltage. More particularly, a boost DC/DC converter converts a DC input voltage with a DC input current into a higher DC output voltage with a lower DC output current. Conversely, a buck DC/DC converter converts a DC input voltage with a DC input current into a lower DC output voltage with a higher DC output current.

A DC/DC converter includes, but not limited to, a set of input power switches, a transformer, and a set of output power switches. The input power switches are controlled to invert the DC input voltage into an AC input voltage. The transformer transforms the AC input voltage into an AC output voltage having a different voltage level. The output power switches are controlled to rectify the AC output voltage into the DC output voltage.

As examples, DC/DC converters may be configured to provide the following DC input/output pairings: 400-12; 48-12; 400-48; and 400-800. As such, for instance, a 400-12 V DC/DC converter may be used to convert a 400 V DC input into a 12 V DC output. Additionally or alternatively, the 400-12 V DC/DC converter may be used between a 400 V DC network and a 12 V DC network to thereby connect these two voltage networks together. Of course, the DC/DC converters are usable over voltage ranges. For instance, the 400-12 V DC/DC converter may be used to convert a DC input voltage falling within a voltage range of 250-470 V DC into a DC output voltage into a 12 V DC output voltage.

A vehicle may have a high-voltage (HV) network and a low-voltage (LV) network. In this case, a DC/DC converter may be used to connect the HV and LV networks together. Consequently, a high DC input voltage of the HV network may be converted by the DC/DC converter into a low DC output voltage for use by loads connected to the LV network. Conversely, assuming the DC/DC converter is bidirectional, a low DC input voltage of the LV network may be converted by the DC/DC converter into a high DC output voltage for use by loads connected to the HV network.

In a DC/DC converter implemented as a packaged electronic component assembly, the power switches and the transformer are mounted on a printed circuit board (PCB). The transformer includes but not limited to, a primary winding, a secondary winding, and a magnetic core. The primary winding may be wrapped around a portion of the magnetic core and the secondary winding may be wrapped around another part of the magnetic core. In one example, both windings may be implemented as respective wirings. In specific cases, both windings may be fully embedded in the PCB.

For reference, a transformer in which both windings are fully embedded in the PCB may not be preferable for creepage or insulation distances. As a component, high electrical currents in the secondary winding may require large physical connections to the associated power switches as well as potting with thermal paste for heat dissipation. Aspects disclosed herein may mitigate creepage or isolation distances and as well as eliminate the need for large physical components (or connections).

As noted above, current vehicle architectures may need DC/DC power conversion to support energy equalization across the different power domains. Several converter architectures may be possible for the respective applications (e.g. 48V/12V DC/DC (bidirectional), 400V/12V DC/DC (unidirectional), 400V/48V DC/DC (unidirectional or bidirectional), 800V/12V DC/DC, etc.). In the low and mid voltage domain, a key factor may be the magnetic integration. It has been experimentally tested that for low and mid voltage power conversion, a hybrid magnetic integration can introduce several benefits in terms of efficiency increase and thermal management. Magnetics for power applications and low voltage may include a bulky integration of conductor wires due to the handling of large electrical currents.

The embodiments as set forth herein may, but not limited to, provide a magnetic assembly that integrated in into a printed circuit board (PCB) on the low/medium voltage domains, while a wound up (or winding) approach may be used for the high voltage area. Such a concept may remove high electrical current interconnections. This approach may also improve power density, thermal management, and design efficiency.

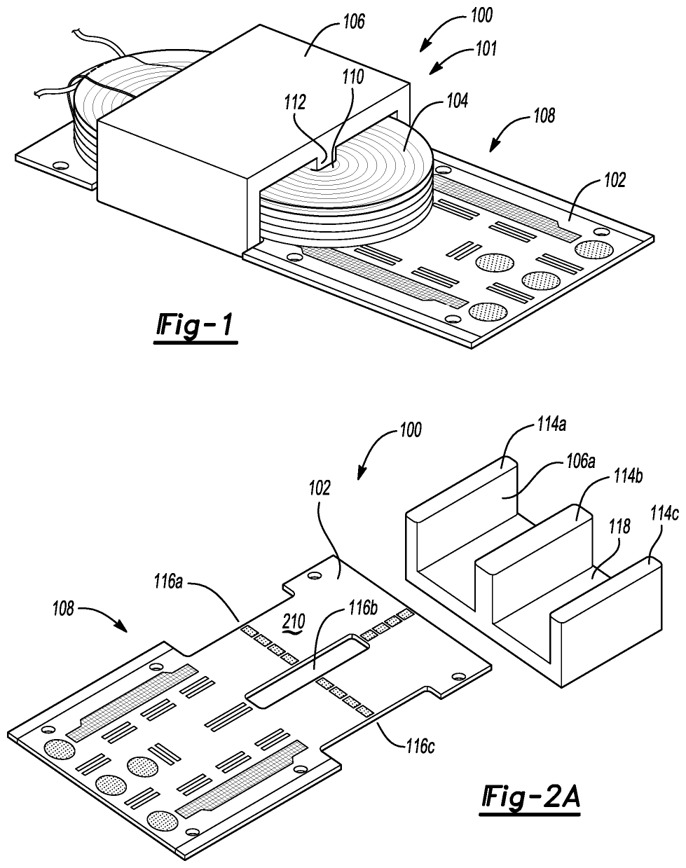

FIG. 1 depicts an example of a perspective view for a transformer implementation (or transformer assembly) 100 in accordance to one embodiment. In one example, the transformer assembly 100 may be used in connection with a 2 KW hybrid transformer implementation for HV-LV DC/DC converter applications. As shown, the transformer assembly 100 includes a printed circuit board (PCB) 102, a primary winding 104, and a magnetic core 106. A plurality of electronics 108 may be positioned on the PCB 102 to enable signal conversion. Such electronics 108 may include any number of controllers (microprocessors), switches (e.g. field effect transistors (FETS), metal oxide semiconductor field effect transistors (MOSFETs), etc.), capacitors, inductors, etc. to enable voltage conversion between two different voltage domains.

A secondary winding 210 (see FIGS. 2A-2B) may be positioned below the primary winding 104. The magnetic core 106 generally surrounds to the primary winding 104 and the secondary winding 210. The primary winding 104, the magnetic core 106, and the secondary winding 210 form a single transformer 101. The secondary winding 210 may be embedded into various layers of the PCB 102 as a magnetic foil. This aspect will be discussed in more detail below. The primary winding 104 may be implemented as a wire assembly, for example, as a Litz wire. As shown, the primary winding 104 may be positioned on a top surface of the PCB 102. Additionally, the primary winding 104 may also be positioned above the secondary winding which is embedded into the layers of the PCB 102. The Litz wire of the primary winding 104 may be wound together to form an opening 110 thereof. A first extending portion 112 of the magnetic core 106 may extend into the opening 110.

FIGS. 2A-2B generally depict one example of the PCB 102 and a lower portion of the magnetic core 106a that form a portion of the transformer assembly 100 of FIG. 1. The magnetic core 106 may be formed of the lower (or first) portion 106a and an upper (or second) portion 106b (not shown in FIGS. 2A-2B). While not shown, the lower portion 106a and the upper portion 106b may be coupled together to form a single magnetic core 106. The lower portion 106a and the upper portion 106b may be coupled together via adhesive or other suitable mechanism. As shown, the lower portion 106a may include a plurality of lower extending portions 114a-114c. The PCB 102 includes a plurality of openings 116a-116c formed therein. The PCB 102 and the secondary winding 210 define the opening 116b. The plurality of lower extending portions 114a-114c of the lower portion 106a are may be inserted via an underside of the PCB 102 into the plurality of openings 116a-116c, respectively (see FIG. 2A). The lower extending portion 114b extends through the PCB 102 and the secondary winding 210. The lower portion 106a of the magnetic core 106 generally includes a generally planar base member 118 (or base member 118) from which the lower extending portions 114a-114c extend therefrom. While the shape of the lower portion 106a may generally be E-shaped, it is recognized that the overall shape and size of the magnetic core 106 may change based on the particular desired implementation. The magnetic core 106 may be formed of a ferrite-based material.

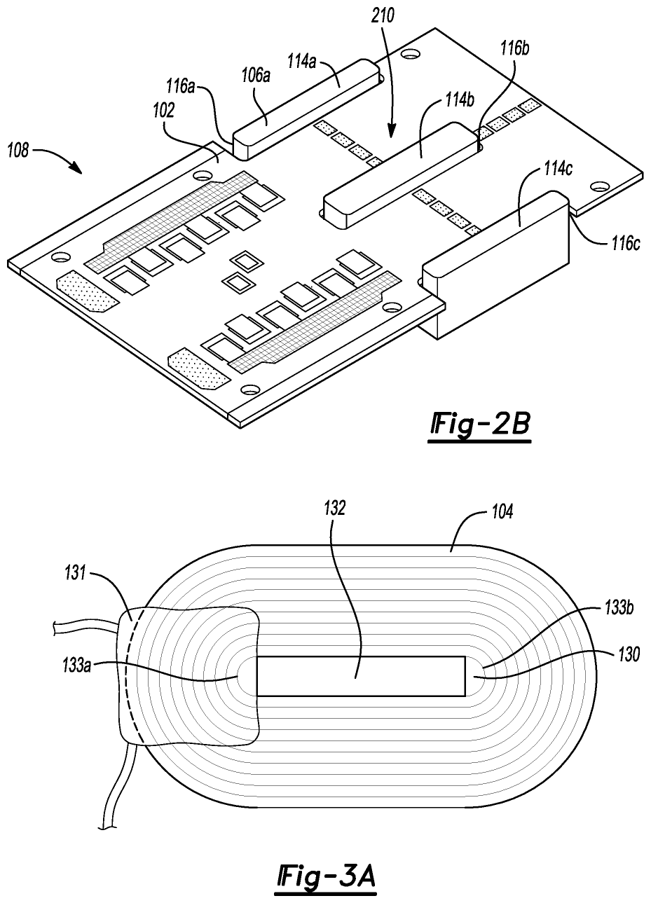

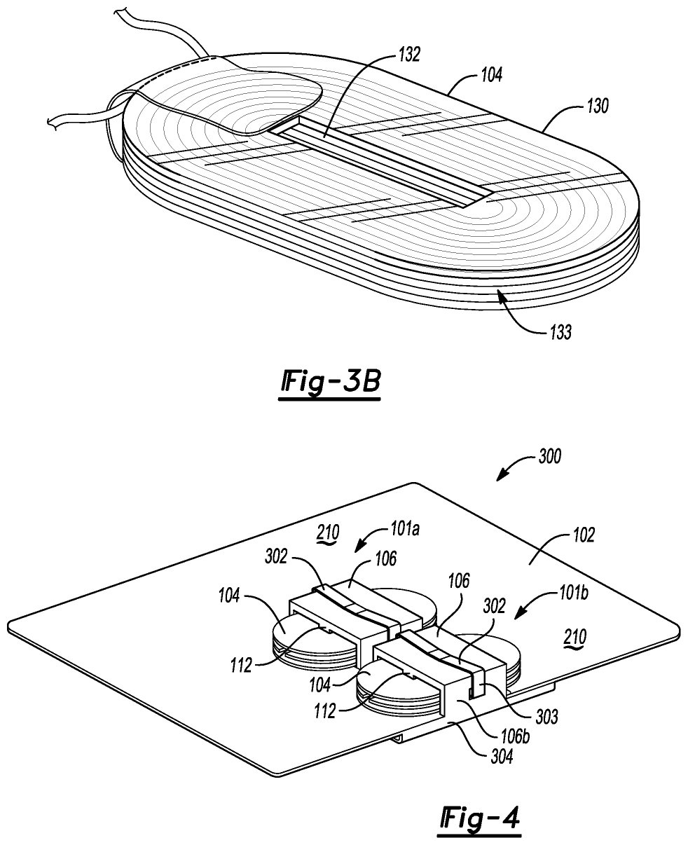

FIGS. 3A-3B generally depict one example of the primary winding 104 that forms at least a portion of the transformer assembly 100 of FIG. 1. As noted above, the primary winding 104 generally includes a wire (e.g., Litz wire). The primary winding 104 also includes a spool 130 that supports the wire of the primary winding 104. The wire may be wound around the spool 130 thereby forming layers of wires which increases the overall size of the package. Specifically, the spool 130 may define an outer channel 133 that extends around an outer perimeter thereof for retaining the wire as the wire is wound around the spool 130 (see FIG. 3B). A fastening mechanism 131 such as tape or adhesive may be coupled to the wires while in the wound position to keep the wires in place with respect to the spool 130. The overall length of the wire may vary based on the amount of inductance that may be needed for a particular desired implementation. The spool 130 defines an opening 132 for receiving the lower extending portion 114b of the lower portion 106a of the magnetic core 106 and the first extending portion 112 of the upper magnetic core 106b. FIG. 3B generally illustrates a back side of the primary winding 104. As shown, the opening 132 extends from the front side of the spool 130 through to the back side of the spool 130 (i.e., from the front side of the primary winding 104 through to the back side of the secondary winding 210). The spool 130 generally includes a first portion 133a having a rounded portion thereof and a second portion 133b also having a rounded potion thereof. The first portion 133a and the second portion 133b are generally positioned on opposite sides of the opening 132 and enable the Litz wire to be wrapped into fitted into the spool 130.

FIG. 4 generally depicts another example of transformer implementation (or transformer assembly) 300 including a plurality of transformers 101a and 101b in accordance to one embodiment. Each of the transformers 101a and 101b include the primary winding 104, the magnetic core 106 (including the lower (or first) portion 106a and the upper (or second) portion 106b) and the secondary winding 210. Thus, the transformer assembly 300 includes the plurality of transformers 101a and 101b to provide increased voltage/power capability. The lower portion 106a and upper portion 106b for each transformer 101a,101b may be coupled together via adhesive or other suitable mechanism.

A spring 302 may be attached to openings 303 that are positioned on sides of the lower portions 106a of the magnetic cores 106, to attach the magnetic cores 106 to the respective primary windings 104 and to the PCB 102. An attachment pad 304 (see also FIG. 6 for reference) may be provided and positioned on an underside of the PCB 102 and may be integrally formed with the lower portion 106a of the magnetic core 106. In this case, the spring 302 when inserted into the openings 303 of the lower portions 106a of the magnetic core 106 apply a downward force against the upper portions 106a of the magnetic core 106 to thereby cause the attachment pad 304 to compress against the underside of the PCB 102. In response to the spring 302 acting on the upper portions 106a of the magnetic core 106 and the attachment pad 304 compressing against the underside of the PCB 102, the magnetic cores 106 compress into the opening 132 and retain the primary windings 104 about the PCB 102.

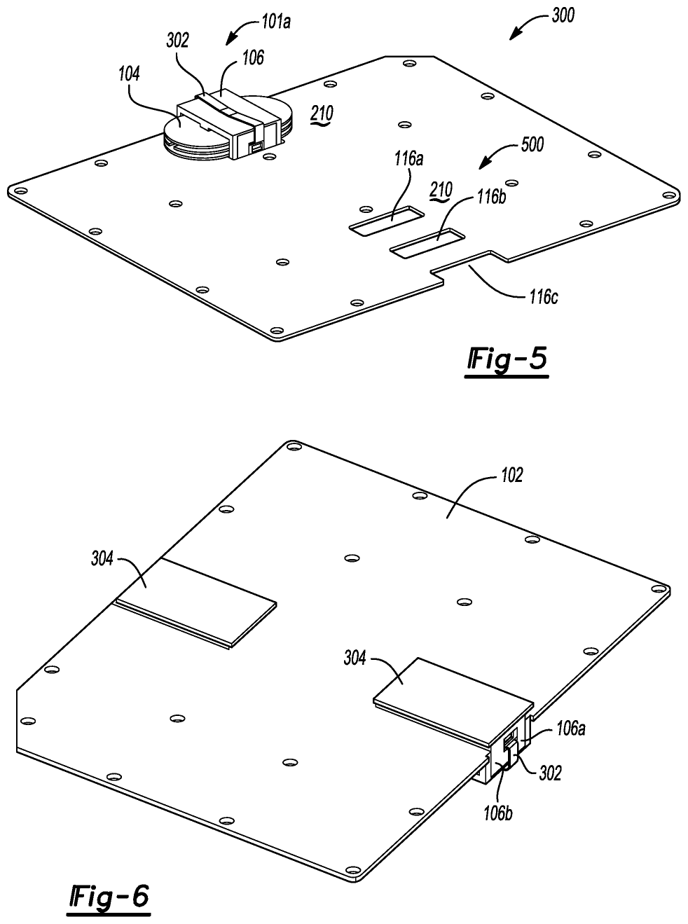

FIG. 5 generally illustrates that the PCB 102 is populated with the transformer 101a in addition to the primary winding 104, the magnetic core 106, and the secondary winding 210. While the PCB 102 may include the transformer 101b as shown in FIG. 4, FIG. 5 illustrates the secondary winding 210 that may be used in connection with the transformer 101b. Each of the secondary windings 210 as illustrated in FIG. 5 may be embedded into the PCB 102.

FIG. 5 also depicts a footprint 500 defined by the PCB 102 for receiving a second primary winding 104b in accordance to one embodiment. The footprint 500 of the PCB 102 generally includes the plurality of openings 116a-116c as noted in connection with FIG. 2A. The plurality of lower extending portions 114a-114c of the lower portion 106a of the magnetic core 107 may be inserted into an underside of the PCB 102 into the plurality of openings 116a-116c, respectively (see reference numbers 114a-114c of the lower portion 106a as set forth in FIG. 2A).

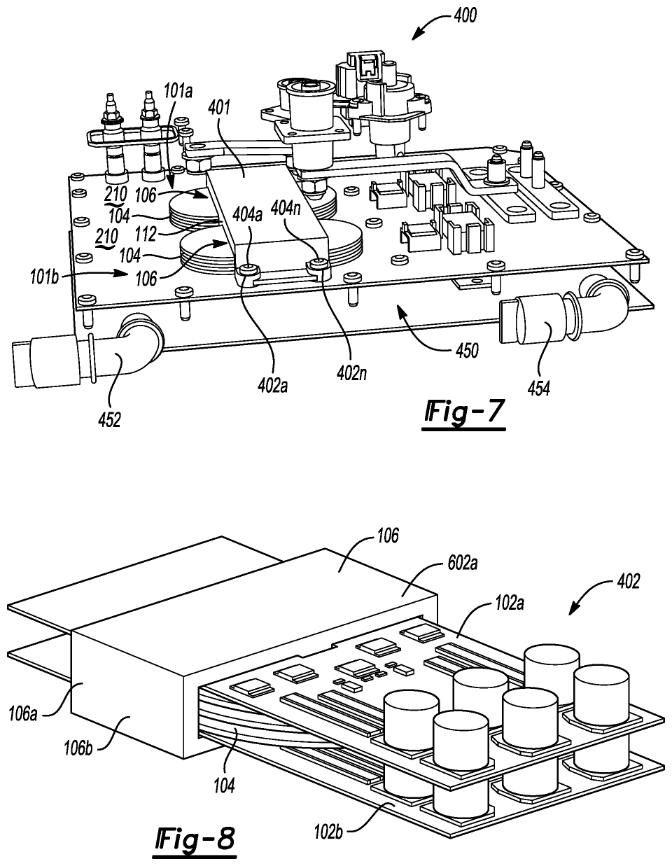

FIG. 7 generally depicts a more detailed example of another transformer assembly 400 in accordance to one embodiment. The transformer assembly 400 generally includes the plurality of transformers 101a, 101b to also provide increased voltage/power capability. The transformer assembly 400 includes various electronics 402 that are positioned on the PCB 102 to perform DC/DC conversion. The transformer assembly 400 is generally similar to the assembly 100 with the exception of multiple transformers being utilized. Each of the transformers 101a and 101b include the primary winding 104, the magnetic core 106 and the secondary winding 210. While not shown in FIG. 7, each magnetic core 106 for each transformer 101a and 101b includes a corresponding lower (or first) portion 106a and an upper (or second) portion 106b. However, in the assembly 400, a fixation element 401 is provided that is positioned over the magnetic cores 106 for the transformer 101a, 101b. The fixation element 401 may be utilized to couple the magnetic cores 106 to the primary coils 104 and to the PCB 102.

The fixation element 401 generally includes a plurality of openings 402a-402n to receive attachment mechanisms 404a-404n. A corresponding attachment mechanism 404a-404n may be inserted into a respective opening 404a-404n to couple the fixation element 401 to the PCB 102. The PCB 102 may include a corresponding opening (not shown) that is positioned below a corresponding opening 402a, 402b, 402c, . . . , 402n to also receive the respective attachment mechanism 404a, 404b, 404c, . . . 402n. Likewise, the lower portions 106a of the magnetic cores 106 may include openings (now shown) to receive the attachment mechanisms 404a-404n. The fixation element 401 applies a downward force against the magnetic cores 106 in response to the attachment mechanisms 404a-404n being inserted into the openings 404a-404n. The first extending portion 112 of the magnetic cores 106 may then be inserted into the openings 110 formed in the primary windings 104 also in response to the attachment mechanisms 404a-404n being inserted into the openings 404a-404n. The fixation element 401 couples the magnetic cores 106, the primary windings 104, the second windings 210 and the PCB 102 to one another.

A cooling chamber (or housing) 450 may be positioned on an underside of the PCB 102. The cooling chamber 450 is generally configured to receive coolant to cool various power elements (or switching devices) that may be positioned on an underside of the PCB 102. In addition, the cooling chamber 450 may also receive the coolant to deliver to the lower portion 106a of the magnetic core 106 to cool the magnetic core 106. The chamber 450 generally includes at least one inlet mechanism 452 and at least one outlet mechanism 454. The coolant may be delivered to the cooling chamber 450 via the inlet mechanism 452 and passed from the cooling chamber 450 via the outlet mechanism 454. A gap (not shown) may be defined between the underside of the PCB 102 and a top side (or top surface) not shown of the cooling chamber 450. In this case, various power electronics that generate heat and the lower portion 106a of the magnetic core 106 may be in contact with the top surface of the cooling chamber 450 to receive the coolant. In general, the coolant contacts the surface of the housing 450 that contacts the heat generating devices on the PCB 102 in addition to an underside of the magnetic core 106 to cool the same. The coolant remains enclosed within the housing 450 and does not directly contact the heat generating device and the magnetic core. The fixation element 401 may also connect to top surface of the housing 450 so that the screws or other attachment mechanisms fix the electronic circuit assembly (transformer, PCB, etc.), while, at the same time, ensure proper contact of the bottom surface of magnetic core 106 with the top surface of the housing 450.

FIG. 8 depicts an example of a perspective view for another transformer assembly 600 in accordance to one embodiment. The transformer implementation 600 generally includes a first PCB 102a, a second PCB 102b, the primary winding 104, the magnetic core 106 including the lower and upper portions 106a, 106b, and various electronics 402. In this case, the first PCB 102a may be positioned on a top side of the primary winding 104 and the second PCB 102b may be positioned on a bottom side of the primary winding 104. A first secondary winding 602a that is implemented as a magnetic foil may be positioned directly above the primary winding 104 and is embedded into the first PCB 102a. The upper portion 602a of the magnetic core 106 may be positioned directly above the secondary winding 104. A second secondary winding 602b that is implemented as a magnetic foil may be positioned directly below the primary winding 104 and is embedded into the second PCB 102b.

The transformer assembly 600 may be implemented as a DC/DC converter that includes two secondaries (e.g., the first secondary winding 602a and the second secondary winding 602b). It is recognized that each of the first secondary winding 602a and the second secondary winding 602b and their corresponding electronics may comprise two parallel circuits that may be generally equal to one another. Each secondary winding 602a, 602b may handle half of the current for the DC/DC converter. This enables the electronics to be at rated at lower voltages which may provide a cost savings. While now shown, it is recognized that the primary winding 104 generally provides an input to each of the first secondary winding 602a and the secondary winding 602b. Additionally, an output is provided between the first PCB 102 and the second PCB 102b to electrically couple these PCBs 102a, 102b to one another.

With reference to FIGS. 2A and 8, each of the first PCB 102a and the second PCB 102b may include the plurality of openings 116a-116c for receiving extending portions 114a-114c of the lower portion 106a and the upper portion 106a of the magnetic core 106. For example, the extending portions 114a-114c from the upper portion 106a of the magnetic core 106 may be inserted through a top side of the first PCB 102a into the plurality of openings 116a-116c, respectively. Similarly, the extending portions 114a-114c from the lower portion 106b of the magnetic core 106 may be inserted through a bottom side of the second PCB 102b into the plurality of openings 116a-116c, respectively. With continuing reference to FIGS. 2A and 8, each of the lower portion 106a and the upper portion 106b of the magnetic core 106 generally includes the base member 118 from which the extending portions 114a-114c extend therefrom.

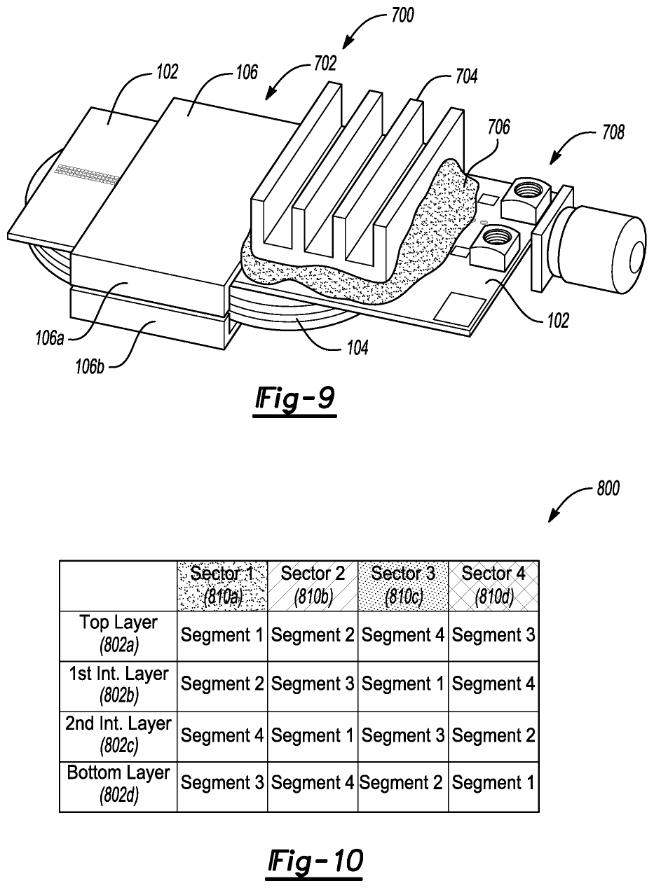

FIG. 9 depicts a perspective view of another transformer assembly 700 in accordance to one embodiment. The transformer implementation 700 generally includes the PCB 102, the primary winding 104, the magnetic core 106 including the upper portion 106a and the lower portion 106b. Similarly, as disclosed above, a secondary winding 702 may be embedded into the PCB 102. A heat sink 704 may be positioned adjacent to the upper portion 106a of the magnetic core 106 and on a top surface of the PCB 102. Thermal paste 706 is provided between the heat sink 704 and the PCB 102 to attach the heat sink 704 to the PCB 102. A plurality of power switching devices 708 (e.g., MOSFETS) may be positioned on the PCB 102 and contact the heat sink 704 and the thermal paste 704. In this case, heat generated by the power switching devices 708 may be transmitted to the thermal paste 706 and to the heat sink 704 to draw heat away from the transformer apparatus 700. The transformer apparatus 700 may provide for a simpler manufacturing process, improved device performance (e.g., improved layout: gating loops and power planes (Vbus)), and an improved secondary winding arrangement to ensure balanced current distribution.

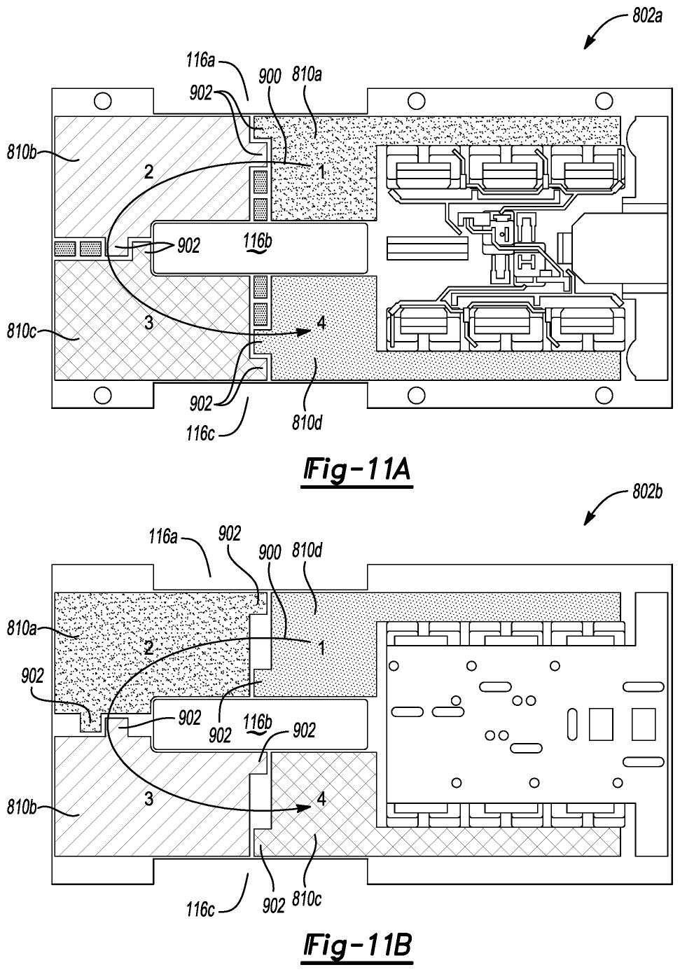

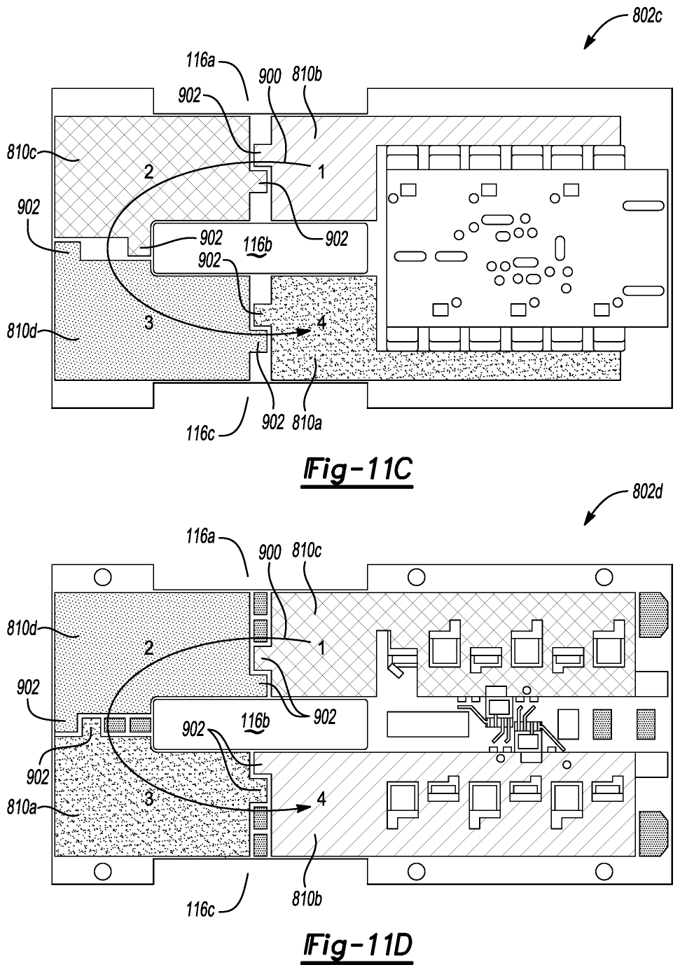

FIG. 10 depicts a table 800 corresponding to partitions of the secondary winding 210 as embedded in various layers 802a-802d of the PCB in accordance to one embodiment. The table 800 illustrates the manner in which various current carrying sectors (i.e., sectors) are positioned on segments of each layer of the PCB 102 and also illustrate the manner in which current flows through the layers 802a-802d. The PCB 102 may comprise a total number of four layers (e.g., a top layer 802a, a first intermediate layer 802b, a second intermediate layer 802c, and a third intermediate layer 802d). Each layer is generally positioned into four segments (e.g., 1, 2, 3, 4) (see also FIGS. 11A-11D) which remain constant from layer to layer (see FIGS. 11A-11D as segments 1, 2, 3, and 4 are similarly designated and positioned in each of these FIGUREs). Per layer 802a, 802b, 802c, 802d, there are corresponding sectors (or current carrying conductors) 810a, 810b, 810c, 810d. In each layer 802a, 802b, 802c, 802d; the various sectors 810a, 810b, 810c, 810d conduct current horizontally in the PCB 102. This will be discussed in more detail below. Table 800 illustrates the vertical positions of the sectors 810a-810d in reference to the segments 1-4 for each respective layer 802a-802d for vertical current flow or alternatively to a description of split current flow per each sector 810a-810b.

Table 800 depicts that each sector 810a-810d is positioned on a different segment for each layer 802a-802d for the PCB 102. This condition may mitigate or minimize the parasitic currents between the corresponding layers 802a-802d since no two vertically adjacent sectors (or segments) are similar to one another. Alternatively, since no two vertically-adjacent sectors in a given segment of the PCB 102 are adjacent in the next segment. By implementing the metallic foil of the secondary winding 800 into the layers 802a-802d of the PCB 102 and into different segments 1-4 for each sector 810a- 810d for each layer 802a-802d, this configuration may ensure that current flows not only on the top or bottom layers 802a and 802d, respectively, of the PCB 102; but also through the first intermediate layer 802b and the second intermediate layer 802c to maximize current flow over a larger cross sectional area of the PCB 102.

FIGS. 11A-11D generally depicts a top view for a corresponding a layer 802a-802d of the PCB 102 with sectors 810a-810d and segments 1-4 of the secondary winding 210 in accordance to one embodiment. Current also flows horizontally through each segment 1, 2, 3, 4 in a corresponding layer 802a-802d. For example, FIGS. 11A-11D illustrate a corresponding current flow 900 starting at segment 1 and on to segment 4 for each layer 810a-810d. Conductive vias 902 are provided to enable current to flow from one segment to another segment (or of the same sector but in a different PCB layer) from one PCB layer to another PCB layer. Likewise, the vias 902 enable current to vertically flow to the different layers 802a-802d.

The vertical flow of current that flows through the various sectors 810a-810d of the layers 802a-802d will be explained as follows (see FIG. 10). In reference to sector 810a, current flows from segment 1 in layer 802a down to segment 2 in layer 802b, down to segment 3 in layer 802d and up to segment 4 in layer 802c.

In reference to sector 810b, current flows from segment 1 in layer 802c, up to segment 2 in layer 802a, down to segment 3 in layer 802b, down to segment 4 in layer 802d (see FIG. 10). In reference to sector 810c, current flows from segment 1 in layer 802d, up to segment 2 in layer 802c, up to segment 3 in layer 802a, down to segment 4 in layer 802b (see FIG. 10). In reference to sector 810d, current flows from segment 1 in layer 802b, down to segment 2 in layer 802d, up to segment 3 in layer 802c, up to segment 4 in layer 802a (see FIG. 10).

In general, for horizontal current flow, each segment conducts the current horizontally in a counter-clockwise direction. Then at each segment end there is a via-array connection to provide a vertical transfer of current to the following segment (in number) but in another PCB layer (as indicated in the table 800). Thus, current may primarily flow horizontally.

The segments are designated such that each sector starts in a segment 1, then connects to a segment 2, then to a segment 3 and finally ends in a segment 4. But for each sector, the order of layers used for each segment is generally different. All segments “1s” in the different layers 802a-802d are interconnected and all segments “4s” in the different layer 804a-804b are interconnected transfer the current to the respective sets of electronic devices (e.g., switches and so on). FIGS. 11A-11D illustrate that each given sector 810a-810d is positioned on a different segment for each layer 802a-802d and this condition may mitigate parasitic currents within the PCB 102.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

What is claimed is:

1. A transformer assembly comprising:
a first printed circuit board (PCB);
a magnetic core positioned about the first PCB;
a primary winding implemented as a wire assembly and being positioned on a first side of the PCB to interface with the magnetic core; and
a secondary winding embedded within the first PCB to interface with the primary winding and the magnetic core to convert an input signal into a converted output signal.

2. The transformer assembly of claim 1, wherein the magnetic core includes a first extending portion that extends through a first opening of the first PCB and the secondary winding and is received in an opening formed in the primary winding.

3. The transformer assembly of claim 2, wherein magnetic core includes a planar base member from which the first extending portion extends thereform.

4. The transformer assembly of claim 3, wherein the first extending portion is positioned at a center of the planar base member.

5. The transformer assembly of claim 4, wherein the planar base member includes a second extending portion and a third extending portion positioned on opposite sides of the planar base member.

6. The transformer assembly of claim 5, wherein the first PCB defines a second opening and a third opening positioned on opposite sides of the first PCB to receive the second extending portion and the third extending portion of the planar base member, respectively.

7. The transformer assembly of claim 6, wherein the magnetic core includes a first portion for being positioned directly above the primary winding.

8. The transformer assembly of claim 1, wherein the wire assembly is a Litz wire.

9. The transformer assembly of claim 1, wherein the wire assembly defines an opening to receive a first extending portion of the magnetic core.

10. The transformer assembly of claim 1, wherein secondary winding is implemented as a metallic foil that is embedded within a plurality of layers that form the first PCB.

11. The transformer assembly of claim 10, wherein the metallic foil is partitioned into a plurality of current carrying sectors, wherein the PCB defines a plurality of segments positioned on each layer of the plurality of layers., and wherein each of the plurality of segments are disposed on the same positions for each layer.

12. The transformer assembly of claim 11, wherein a first current carrying sector is positioned on a different segment for each layer to reduce parasitic currents in the assembly.

13. The transformer assembly of claim 1, further comprising a second PCB positioned above the first PCB and the primary winding.

14. The transformer assembly of claim 13, wherein the magnetic core surrounds at least a portion of the first PCB and the second PCB.

15. The transformer assembly of claim 1 is implemented in a direct current (DC) to DC converter.

16. A power conversion device comprising:
a transformer assembly to receive an input signal, the transformer assembly including:
a first printed circuit board (PCB);
a magnetic core positioned about the first PCB;
a primary winding implemented as a wire assembly and being positioned on a first side of the PCB to interface with the magnetic core; and
a secondary winding embedded within the first PCB to interface with the primary winding and the magnetic core to convert the input signal into a converted output signal.

17. The power conversion device of claim 16, wherein the wire assembly is a Litz wire.

18. The transformer assembly of claim 16, wherein the wire assembly defines an opening to receive a first extending portion of the magnetic core.

19. The transformer assembly of claim 16, wherein secondary winding is implemented as a metallic foil that is embedded within a plurality of layers that form the first PCB.

20. A transformer assembly comprising:
a printed circuit board (PCB);
a magnetic core positioned about the PCB;
a primary winding implemented as a Litz wire and being positioned on a first side of the PCB to interface with the magnetic core; and
a secondary winding embedded within the first PCB to interface with the primary winding and the magnetic core to convert an input signal into a converted output signal.
